(19) United States
(12) Patent Application Publication
(10) Pub. No.: US 2013/0005234 A1
(43) Pub. Date: Jan. 3, 2013

(54) COOLING SYSTEM

(75) Inventor: Ben-Chiao Jai, Taoyuan Hsien (TW)

(73) Assignee: DELTA ELECTRONICS, INC., Taoyuan Hsien (TW)

(21) Appl. No.: 13/197,971

(22) Filed: Aug. 4, 2011

(30) Foreign Application Priority Data
Jun. 29, 2011 (TW) 100122884

(51) Int. Cl. H05K 5/02

(52) U.S. Cl. 454/184

(57) ABSTRACT

A cooling system includes a computer room, at least one rack cabinet, at least one air conditioner, a first airflow path switching unit and a second airflow path switching unit. The first airflow path switching unit is in fluid communication with an airflow inlet of the air conditioner and an airflow exhaust gate of the computer room. The first airflow path switching unit includes a first blocking element. The second airflow path switching unit is in fluid communication with an airflow outlet of the air conditioner and an airflow intake gate of the computer room. The second airflow path switching unit includes a second blocking element. An airflow path is switched by the first blocking element and the second blocking element according to an operating status of the air conditioner, so that the computer room is operated in an internal circulation mode or an external circulation mode.

### FIELD OF THE INVENTION

The present invention relates to a cooling system, and more particularly to a cooling system that is selectively operated in an internal circulation mode or an external circulation mode.

### BACKGROUND OF THE INVENTION

With increasing development of information industries and networks, the services provided through networks are becoming more and more appealing in various applications. Recently, the concepts of the cloud computing technology have been emerged, and thus the data center becomes more important. A data center is a facility used to house a plurality of computers, servers, storage devices and/or network communication devices. For providing intensive network applications, the numbers and operating speeds of the computers, servers, the storage devices and/or the network communication devices of the data center need to be increased to exchange and store more data.

In the data center, the computers, servers, the storage devices and/or the network communication devices are usually installed in corresponding rack cabinets. These rack cabinets are arranged in one or more rows. As known, the serves and other electronic devices of the data center are continuously operated all the day. Since these electronic devices are installed within a close space of the data center, a substantial amount of heat is generated during operations of these electronic devices. If the heat is not effectively dissipated away, the performance of these electronic devices will be deteriorated or these electronic devices may have breakdown. For maintaining efficient operations of these electronic devices, the data center is equipped with a plurality of air conditioners to provide a controlled environment.

That is, the airflow is circulated within the close space of the data center. Generally, the heated airflow from the operating electronic devices is guided to the heat exchangers of the air conditioners, so that a great deal of heat can be removed. Consequently, a cooled airflow may be guided from the air conditioners to the operating electronic devices again. Since the airflow is continuously circulated within the data center, the temperature of the data center can be properly adjusted. Likewise, the air conditioners of the data centers should be continuously operated to maintain and reduce the temperature of the data center. If some of the air conditioners within the computer room are abnormal or damaged or have insufficient cooling capability, the heat generated by the electronic devices fails to be effectively removed. Since the heat within the computer room is continuously accumulated, the performance of the electronic devices of the rack cabinet will be impaired or the electronic devices may be damaged.

### SUMMARY OF THE INVENTION

The present invention provides a cooling system, in which the computer room is selectively operated in an internal circulation mode or an external circulation mode. In a case that some of the air conditioners within the computer room are abnormal or damaged or have insufficient cooling capability, the operating mode of the computer room is switched from the internal circulation mode to an external circulation mode. Since the heat within the computer room can be effectively removed, the possibility of causing damage or impairing performance of the electronic devices of the rack cabinet will be largely reduced.

The present invention also provides a cooling system, in which the operating mode of the computer room of the cooling system can be adaptively switched between the internal circulation mode and the external circulation mode. Consequently, the temperature of the computer room can be effectively maintained and reduced, and the electronic devices within the rack cabinet can be continuously and normally operated.

In accordance with an aspect of the present invention, there is provided a cooling system. The cooling system includes a computer room, at least one rack cabinet, at least one air conditioner, a first airflow path switching unit and a second airflow path switching unit. The computer room includes an inner space, an airflow exhaust gate and an airflow intake gate. The rack cabinet is installed within the inner space of the computer room. The air conditioner is installed within the inner space for cooling the inner space and adjusting a temperature of the inner space. The air conditioner includes an airflow inlet and an airflow outlet. The first airflow path switching unit is in fluid communication with the airflow inlet and the airflow exhaust gate. The first airflow path switching unit includes a first blocking element. The second airflow path switching unit is in fluid communication with the airflow outlet and the airflow intake gate. The second airflow path switching unit includes a second blocking element. An airflow path is switched by the first blocking element and the second blocking element according to an operating status of the air conditioner, so that the computer room is operated in an internal circulation mode or an external circulation mode.

In accordance with another aspect of the present invention, there is provided a cooling system. The cooling system includes a computer room, at least one rack cabinet, at least one air conditioner, a first airflow path switching unit and a second airflow path switching unit. The computer room includes an inner space, an airflow exhaust gate and an airflow intake gate. The rack cabinet is installed within the inner space of the computer room. The air conditioner is installed within the inner space for cooling the inner space and adjusting a temperature of the inner space, so that the heat is removed by the air conditioner. The air conditioner includes an airflow inlet and an airflow outlet. The first airflow path switching unit is in fluid communication with the airflow inlet and the airflow exhaust gate. The first airflow path switching unit includes a first blocking element. The second airflow path switching unit is in fluid communication with the airflow outlet and the airflow intake gate. The second airflow path switching unit includes a second blocking element. An airflow path is switched by the first blocking element and the second blocking element according to an operating status of the air conditioner, so that the computer room is operated in an internal circulation mode or an external circulation mode. When the computer room is operated in the external circulation mode, an ambient cool airflow is inhaled into the inner space through the airflow intake gate, and a heated airflow within the computer room is exhausted to surroundings through the airflow exhaust gate.

In accordance with another aspect of the present invention, there is provided a cooling system. The cooling system includes a computer room, at least one rack cabinet, at least one air conditioner, a first airflow path switching unit, a second airflow path switching unit, at least one detecting unit and a controlling unit. The computer room includes an inner space, an airflow exhaust gate and an airflow intake gate. The rack cabinet is installed within the inner space of the computer room. The air conditioner is installed within the inner space for adjusting a temperature of the inner space. The air conditioner includes an airflow inlet and an airflow outlet. The first airflow path switching unit is in fluid communication with the airflow inlet and the airflow exhaust gate. The first airflow path switching unit includes a first blocking element. The second airflow path switching unit is in fluid communication with the airflow outlet and the airflow intake gate. The second airflow path switching unit includes a second blocking element. The detecting unit is used for detecting an operating status of the air conditioner and issuing a corresponding detecting signal. The controlling unit is connected with the detecting unit, the first blocking element and the second blocking element for controlling the first blocking element and the second blocking element to switch an airflow path in response to the detecting signal, so that the computer room is operated in an internal circulation mode or an external circulation mode.

The above contents of the present invention will become more readily apparent to those ordinarily skilled in the art after reviewing the following detailed description and accompanying drawings, in which:

### BRIEF DESCRIPTION OF THE DRAWINGS

FIG. 1A schematically illustrates a cooling system in an internal circulation mode according to an embodiment of the present invention;

FIG. 1B schematically illustrates a cooling system in an external circulation mode according to an embodiment of the present invention;

FIG. 2A schematically illustrates a cooling system in an internal circulation mode according to another embodiment of the present invention;

FIG. 2B schematically illustrates a cooling system in an external circulation mode according to another embodiment of the present invention;

FIG. 3 schematically illustrates a controlling mechanism of the cooling system of the present invention;

FIG. 4A schematically illustrates a cooling system in an internal circulation mode according to another embodiment of the present invention; and

FIG. 4B schematically illustrates a cooling system in an external circulation mode according to another embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

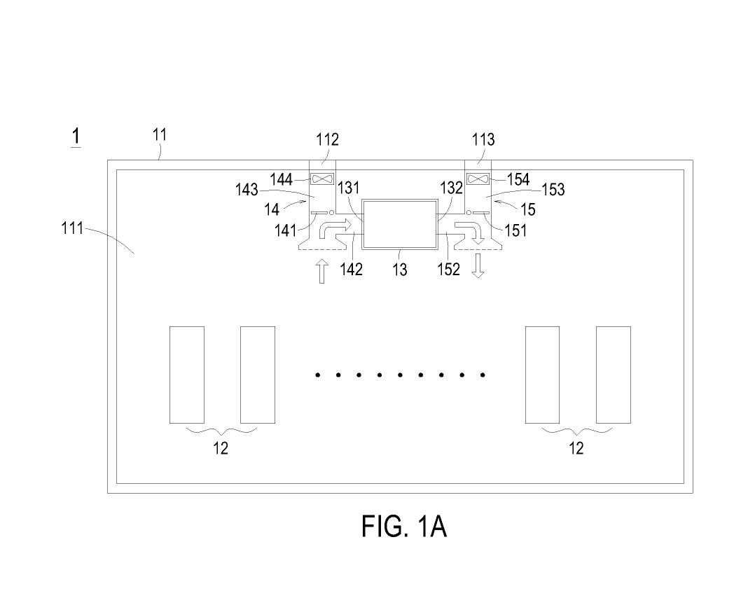

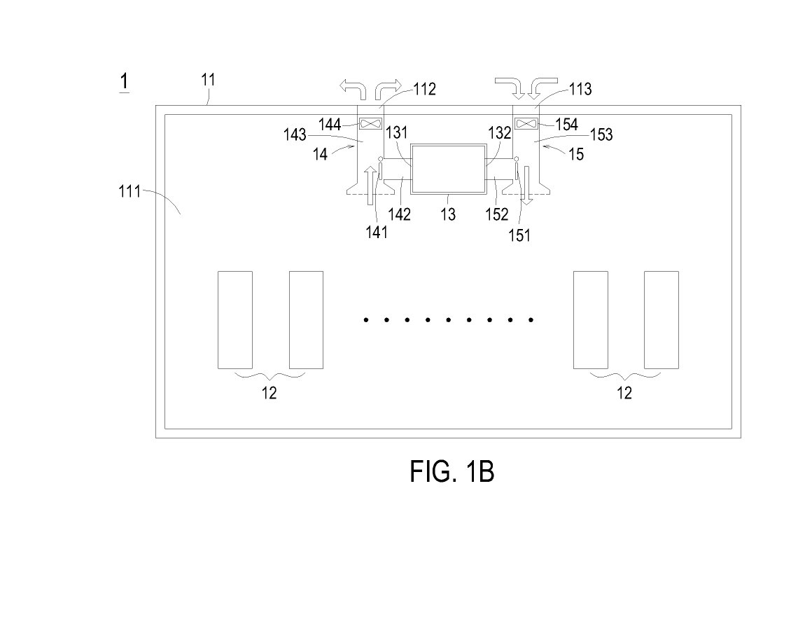

FIG. 1A schematically illustrates a cooling system in an internal circulation mode according to an embodiment of the present invention. FIG. 1B schematically illustrates a cooling system in an external circulation mode according to an embodiment of the present invention. As shown in FIGS. 1A and 1B, the cooling system 1 comprises a computer room 11, one or more rack cabinets 12, at least one air conditioner 13, a first airflow path switching unit 14 and a second airflow path switching unit 15. The computer room 11 has a close inner space 111, an airflow exhaust gate 112 and an airflow intake gate 113. The rack cabinets 12 are installed within the inner space 111 of the computer room 11. These rack cabinets 12 are arranged in a row. One or more electronic devices (e.g. computers, servers, storage devices and/or network communication devices) are installed within each rack cabinet 12. During operations, the heat generated by the operating electronic devices is dissipated to the inner space 111 of the computer room 11 through heat exchange. The at least one air conditioner 13 is installed within the inner space 111 of the computer room 11, and located in the vicinity of the airflow exhaust gate 112 and the airflow intake gate 113. Moreover, the air conditioner 13 comprises an airflow inlet 131 and an airflow outlet 132. The air conditioner 13 is configured for cooling and adjusting the temperature within the inner space 111 of the computer room 11, thereby removing the heat from the electronic devices of the rack cabinets 12.

The first airflow path switching unit 14 is located between the airflow inlet 131 of the air conditioner 13 and the airflow exhaust gate 112 of the computer room 11. Moreover, the first airflow path switching unit 14 is in fluid communication with the airflow inlet 131 of the air conditioner 13 and the airflow exhaust gate 112 of the computer room 11. The second airflow path switching unit 15 is located between the airflow outlet 132 of the air conditioner 13 and the airflow intake gate 113 of the computer room 11. Moreover, the second airflow path switching unit 15 is in fluid communication with the airflow outlet 132 of the air conditioner 13 and the airflow intake gate 113 of the computer room 11.

The first airflow path switching unit 14 comprises a first blocking element 141, a first internal circulation path 142 and a first external circulation path 143. Through the first internal circulation path 142, the airflow inlet 131 of the air conditioner 13 and the inner space 111 of the computer room 11 are in fluid communication with each other. Through the first external circulation path 143, the airflow exhaust gate 112 of the computer room 11 and the inner space 111 of the computer room 11 are in fluid communication with each other. Through the first blocking element 141, the first internal circulation path 142 or the first external circulation path 143 is selectively blocked. The second airflow path switching unit 15 comprises a second blocking element 151, a second internal circulation path 152 and a second external circulation path 153. Through the second internal circulation path 152, the airflow outlet 132 of the air conditioner 13 and the inner space 111 of the computer room 11 are in fluid communication with each other. Through the second external circulation path 153, the airflow intake gate 113 of the computer room 11 and the inner space 111 of the computer room 11 are in fluid communication with each other. Through the second blocking element 151, the second internal circulation path 152 or the second external circulation path 153 is selectively blocked.

According to the operating status of the air conditioner 13, the first external circulation path 143 or the first internal circulation path 142 is selectively blocked by the first blocking element 141 of the first airflow path switching unit 14, so that the computer room 11 is operated in an internal circulation mode or an external circulation mode. Similarly, according to the operating status of the air conditioner 13, the second external circulation path 153 or the second internal circulation path 152 is selectively blocked by the second blocking element 151 of the second airflow path switching unit 15, so that the computer room 11 is operated in the internal circulation mode or the external circulation mode. In an embodiment, the first blocking element 141 of the first airflow path switching unit 14 and the second blocking element 151 of the second airflow path switching unit 15 are air doors.

Please refer to FIG. 1A again. In a case that the air conditioner 13 within the computer room 11 is normally operated or the cooling capability thereof is sufficient, the first external circulation path 143 is blocked by the first blocking element 141, but the first internal circulation path 142 is in fluid communication. Consequently, the airflow inlet 131 of the air conditioner 13 is in fluid communication with the inner space 111 of the computer room 11. At the same time, the second external circulation path 153 is blocked by the second blocking element 151, but the second internal circulation path 152 is in fluid communication. Consequently, the airflow outlet 132 of the air conditioner 13 is in fluid communication with the inner space 111 of the computer room 11. Under this circumstance, the computer room 11 is operated in an internal circulation mode, and the air conditioner 13 is capable of maintaining or reducing the temperature of the inner space 111 of the computer room 11.

Please refer to FIG. 1B again. Whereas, in a case that the air conditioner 13 within the computer room 11 is abnormal, damaged or the cooling capability thereof is insufficient, the first internal circulation path 142 is blocked by the first blocking element 141, but the first external circulation path 143 is in fluid communication. Consequently, the airflow exhaust gate 112 of the computer room 11 is in fluid communication with the inner space 111 of the computer room 11. At the same time, the second internal circulation path 152 is blocked by the second blocking element 151, but the second external circulation path 153 is in fluid communication. Consequently, the airflow intake gate 113 of the computer room 11 is in fluid communication with the inner space 111 of the computer room 11. Under this circumstance, the operating mode of the computer room 11 is switched from the internal circulation mode to an external circulation mode. In the external circulation mode, the ambient cool airflow may be inhaled into the inner space 111 of the computer room 11, and the heated airflow within the computer room 11 may be exhausted to the surroundings. In such way, since the heat within the computer room 11 can be effectively removed, the possibility of causing damage or impairing performance of the electronic devices of the rack cabinet 12 will be largely reduced.

Please refer to FIGS. 1A and 1B again. The first airflow path switching unit 14 further comprises a first fan 144. The first fan 144 is located between the airflow exhaust gate 112 of the computer room 11 and the first blocking element 141. That is, the first fan 144 is located in the first external circulation path 143 for driving the airflow, thereby facilitating exhausting the heated airflow to the surroundings through the airflow exhaust gate 112. The second airflow path switching unit 15 further comprises a second fan 154. The second fan 154 is located between the airflow intake gate 113 of the computer room 11 and the second blocking element 151. That is, the second fan 154 is located in the second external circulation path 153, thereby facilitating inhaling the external cool airflow into the inner space 111 of the computer room 11.

In a case that the air conditioner 13 within the computer room 11 is normally operated or the cooling capability thereof is sufficient, the first internal circulation path 142 is in fluid communication by the first airflow path switching unit 14 and the second internal circulation path 152 is in fluid communication by the second airflow path switching unit 15. In this situation, the first fan 144 and the second fan 154 are disabled. Under this circumstance, the computer room 11 is operated in the internal circulation mode. Whereas, in a case that the air conditioner 13 within the computer room 11 is abnormal, damaged or the cooling capability thereof is insufficient, the first external circulation path 143 is in fluid communication by the first airflow path switching unit 14 and the second external circulation path 153 is in fluid communication by the second airflow path switching unit 15. Meanwhile, the first fan 144 and the second fan 154 are simultaneously enabled to drive the airflow. Under this circumstance, the computer room 11 is operated in the external circulation mode.

In some embodiments, the air conditioner 13 comprises a plurality of air-conditioning units, which are connected in parallel. Moreover, an example of the air conditioner 13 includes but is not limited to an upward-blowing air conditioner, a side-blowing air conditioner or a downward-blowing air conditioner. The computer room 11 is a computer room of a data center. In particular, the computer room 11 is a fixed computer room constructed in a building data center, or the computer room 11 is a shipping computer room constructed in a portable data center.

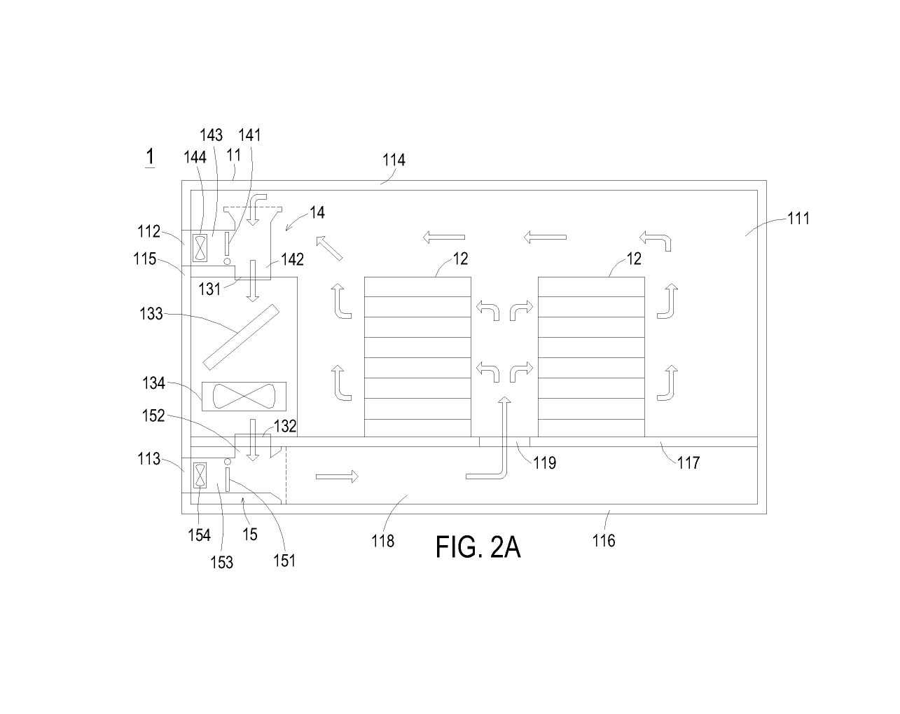

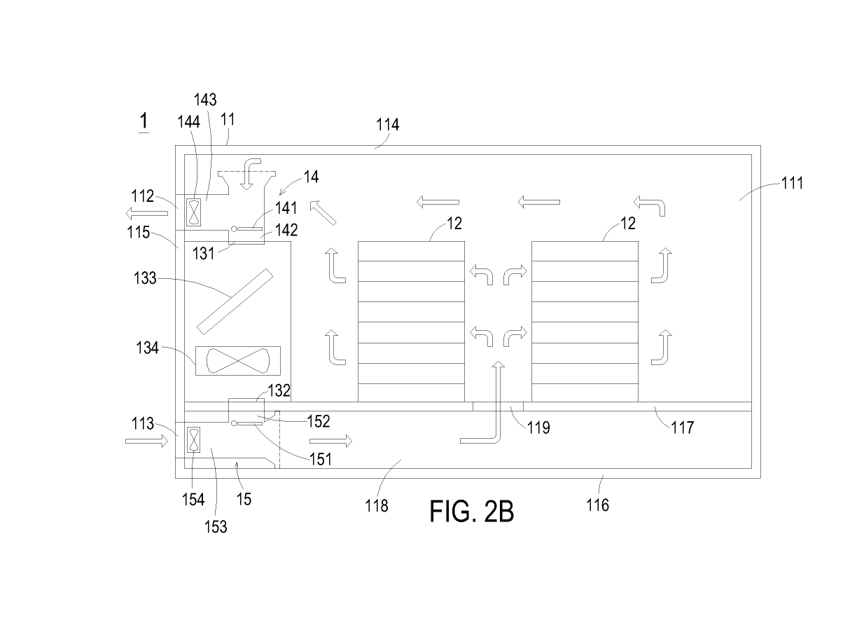

FIG. 2A schematically illustrates a cooling system in an internal circulation mode according to another embodiment of the present invention. FIG. 2B schematically illustrates a cooling system in an external circulation mode according to another embodiment of the present invention. As shown in FIGS. 2A and 2B, the cooling system 1 comprises a computer room 11, one or more rack cabinets 12, at least one air conditioner 13, a first airflow path switching unit 14 and a second airflow path switching unit 15. The operating principles and configurations of these components are similar to those of the above embodiment, and are not redundantly described herein. In this embodiment, the computer room 11 further comprises a top wall 114, a plurality of side walls 115, a bottom wall 116 and a floor 117. The inner space 111 of the computer room 11 is defined by the top wall 114, the side walls 115 and the bottom wall 116. The airflow exhaust gate 112 and the airflow intake gate 113 of the computer room 11 may be located at the same wall or different walls. Moreover, an airflow channel 118 is defined by the side walls 115, the bottom wall 116 and the floor 117. The floor 117 has a plurality of ventilation holes 119. Through the airflow channel 118 and the ventilation holes 119, the cool airflow from the air conditioner 13 may be introduced into the inner space 111 of the computer room 11.

The rack cabinets 12 and the air conditioner 13 are all disposed within the inner space 111 of the computer room 11 and on the floor 117. An example of the air conditioner 13 is a downward-blowing air conditioner. The airflow outlet 132 of the air conditioner 13 is in fluid communication with the airflow channel 118 through the second airflow path switching unit 15. The first airflow path switching unit 14 is disposed above the air conditioner 13. The second airflow path switching unit 15 is located in the airflow channel 118. In this embodiment, the air conditioner 13 comprises a heat exchanger 133 and a first airflow driving device 134. The heat of hot airflow inhaled into the airflow inlet 131 of the air conditioner 13 is partially removed by the heat exchanger 133, and thus a cooled airflow is discharged from the airflow outlet 132 of the air conditioner 13. The first airflow driving device 134 is used for driving the airflow.

Please refer to FIG. 2A again. In a case that the air conditioner 13 within the computer room 11 is normally operated or the cooling capability thereof is sufficient, the first external circulation path 143 is blocked by the first blocking element 141, but the first internal circulation path 142 is in fluid communication. Consequently, the airflow inlet 131 of the air conditioner 13 is in fluid communication with the inner space 111 of the computer room 11. At the same time, the second external circulation path 153 is blocked by the second blocking element 151, but the second internal circulation path 152 is in fluid communication. Consequently, the airflow outlet 132 of the air conditioner 13 is in fluid communication with the inner space 111 of the computer room 11. Under this circumstance, the computer room 11 is operated in an internal circulation mode, and the air conditioner 13 is capable of maintaining or reducing the temperature of the inner space 111 of the computer room 11.

Please refer to FIG. 2B again. Whereas, in a case that the air conditioner 13 within the computer room 11 is abnormal, damaged or the cooling capability thereof is insufficient, the first internal circulation path 142 is blocked by the first blocking element 141, but the first external circulation path 143 is in fluid communication. Consequently, the airflow exhaust gate 112 of the computer room 11 is in fluid communication with the inner space 111 of the computer room 11. At the same time, the second internal circulation path 152 is blocked by the second blocking element 151, but the second external circulation path 153 is in fluid communication. Consequently, the airflow intake gate 113 of the computer room 11 is in fluid communication with the airflow channel 118 and the inner space 111 of the computer room 11. Under this circumstance, the operating mode of the computer room 11 is switched from the internal circulation mode to an external circulation mode. In the external circulation mode, the ambient cool airflow may be inhaled into the airflow channel 118 and the inner space 111 of the computer room 11, and the heated airflow within the computer room 11 may be exhausted to the surroundings. In such way, since the heat within the computer room 11 can be effectively removed, the possibility of causing damage or impairing performance of the electronic devices of the rack cabinet 12 will be largely reduced.

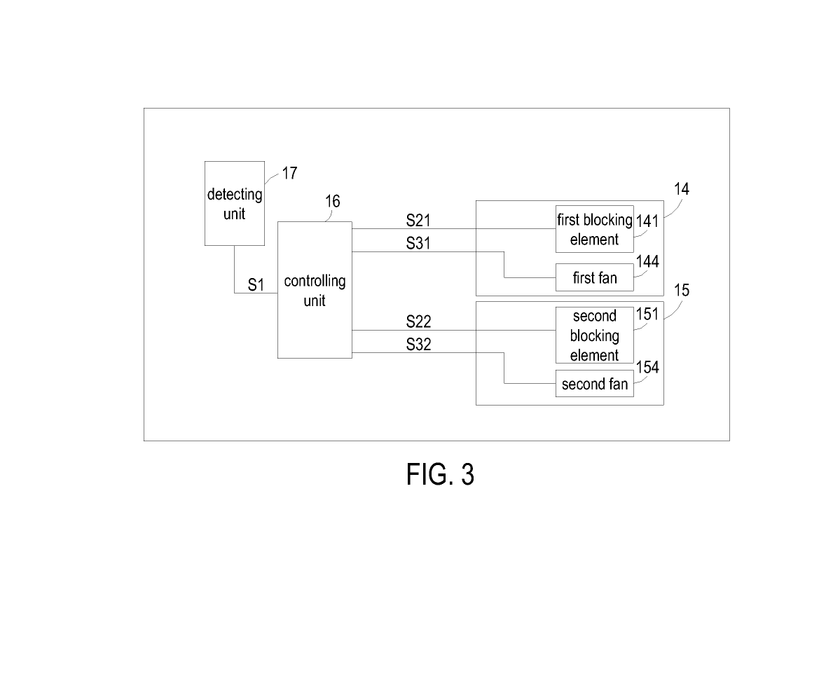

FIG. 3 schematically illustrates a controlling mechanism of the cooling system of the present invention. The cooling system 1 further comprises a controlling unit 16 and at least one detecting unit 17. The controlling unit 16 is connected with the detecting unit 17, the first blocking element 141 and the first fan 144 of the first airflow path switching unit 14 and the second blocking element 151 and the second fan 154 of the second airflow path switching unit 15. The detecting unit 17 is used for detecting an operating status of the air conditioner 13, and issuing a corresponding detecting signal S1 to the controlling unit 16. In response to the detecting signal S1, the controlling unit 16 issues a first switching signal S21 and a second switching signal S22 to the first blocking element 141 and the second blocking element 151, respectively. According to the operating status of the air conditioner 13, the actions of the first blocking element 141 and the second blocking element 151 are controlled by the controlling unit 16.

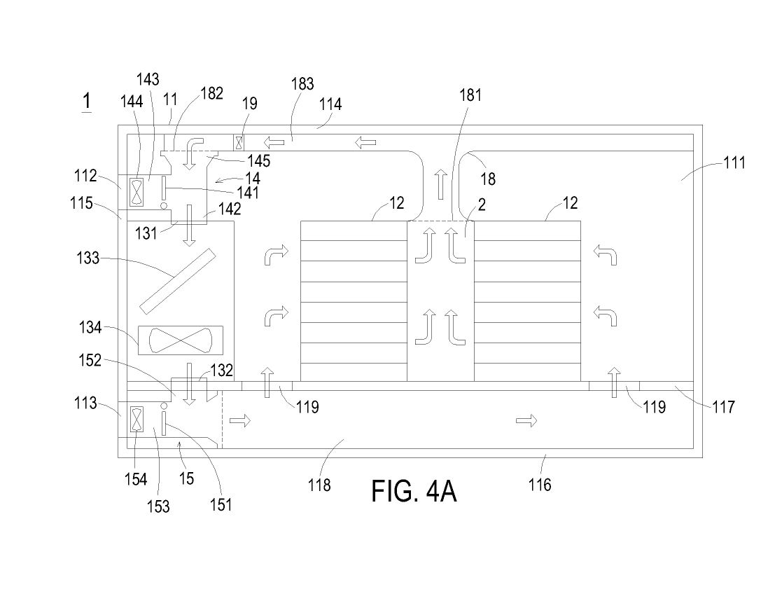

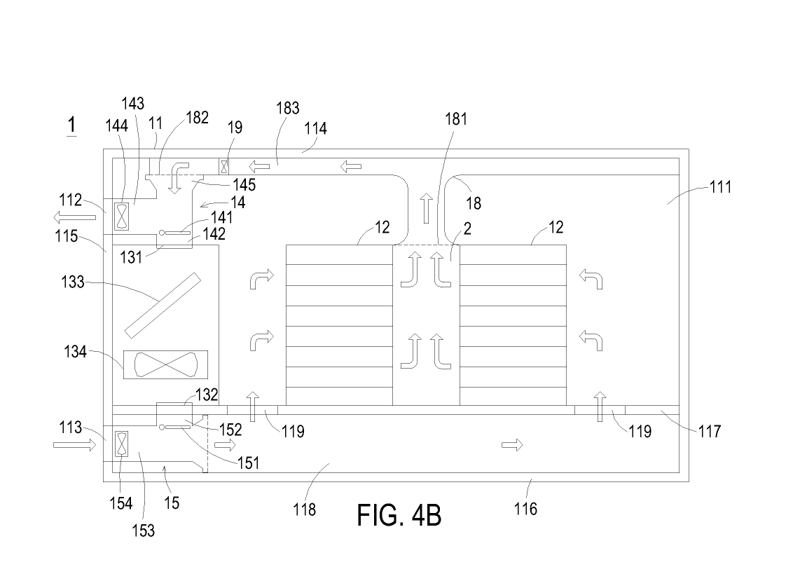

Moreover, in response to the detecting signal S1, the controlling unit 16 also issues a first driving signal S31 and a second driving signal S32 to the first fan 144 and the second fan 154, respectively. According to the operating status of the air conditioner 13, the actions of the first fan 144 and the second fan 154 are controlled by the controlling unit 16. The actions of the first blocking element 141, the first fan 144, the second blocking element 151 and the second fan 154 are similar to those illustrated in the above embodiments, and are not redundantly described herein. In some embodiments, the controlling unit 13 is a controller for controlling the air conditioner 13 or a system controller for controlling the computer room 11. FIG. 4A schematically illustrates a cooling system in an internal circulation mode according to another embodiment of the present invention. FIG. 4B schematically illustrates a cooling system in an external circulation mode according to another embodiment of the present invention. As shown in FIGS. 4A and 4B, the cooling system 1 comprises a computer room 11, a plurality of rack cabinets 12, at least one air conditioner 13, a first airflow path switching unit 14 and a second airflow path switching unit 15. The operating principles and configurations of these components are similar to those of the cooling system as shown in FIGS. 2A and 2B, and are not redundantly described herein. Comparing with the cooling system as shown in FIGS. 2A and 2B, the cooling system 1 further includes a guiding device 18 and a second airflow driving device 19 and a hot zone 2 defined by the plural rack cabinets 12. The guiding device 18 is disposed in the inner space 111 of the computer room 11 and has an inlet 181, an outlet 182 and an airflow passage 183. The inlet 181 is in fluid communication with the hot zone 2 defined by the rack cabinets 12, and the outlet 182 is in fluid communication with an inlet 145 of the first airflow path switching unit 14. The guiding device 18 is configured for guiding the hot airflow in the hot zone 2 to the inlet 145 of the first airflow path switching unit 14. The second airflow driving device 19 is disposed in the airflow passage 183 of the guiding device 18 for driving airflow.

Please refer to FIG. 4A again. In a case that the air conditioner 13 within the computer room 11 is normally operated or the cooling capability thereof is sufficient, the first external circulation path 143 is blocked by the first blocking element 141, but the first internal circulation path 142 is in fluid communication. Consequently, the airflow inlet 131 of the air conditioner 13 is in fluid communication with the hot zone 2 through the first airflow path switching unit 14 and the guiding device 18. At the same time, the second external circulation path 153 is blocked by the second blocking element 151, but the second internal circulation path 152 is in fluid communication. Consequently, the airflow outlet 132 of the air conditioner 13 is in fluid communication with the airflow channel 118 and the inner space 111 of the computer room 11. Under this circumstance, the computer room 11 is operated in an internal circulation mode, and the air conditioner 13 is capable of maintaining or reducing the temperature of the inner space 111 of the computer room 11.

Please refer to FIG. 4B again. Whereas, in a case that the air conditioner 13 within the computer room 11 is abnormal, damaged or the cooling capability thereof is insufficient, the first internal circulation path 142 is blocked by the first blocking element 141, but the first external circulation path 143 is in fluid communication. Consequently, the airflow exhaust gate 112 of the computer room 11 is in fluid communication with the hot zone 2 through the first airflow path switching unit 14 and the guiding device 18. At the same time, the second internal circulation path 152 is blocked by the second blocking element 151, but the second external circulation path 153 is in fluid communication. Consequently, the airflow intake gate 113 of the computer room 11 is in fluid communication with the airflow channel 118 and the inner space 111 of the computer room 11. Under this circumstance, the operating mode of the computer room 11 is switched from the internal circulation mode to an external circulation mode. In the external circulation mode, the ambient cool airflow may be inhaled into the airflow channel 118 and the inner space 111 of the computer room 11, and the heated airflow within the computer room 11 may be exhausted to the surroundings through the first airflow path switching unit 14 and the guiding device 18. In such way, since the heat within the computer room 11 can be effectively removed, the possibility of causing damage or impairing performance of the electronic devices of the rack cabinet 12 will be largely reduced.

From the above description, the present invention provides a cooling system for use in a data center. The computer room of the data center is selectively operated in an internal circulation mode or an external circulation mode. In a case that some of the air conditioners within the computer room are abnormal or damaged or have insufficient cooling capability, the operating mode of the computer room is switched from the internal circulation mode to an external circulation mode. In such way, since the heat within the computer room can be effectively removed, the possibility of causing damage or impairing performance of the electronic devices of the rack cabinet will be largely reduced. Moreover, since the operating mode of the computer room can be adaptively switched between the internal circulation mode and the external circulation mode, the temperature of the computer room can be effectively maintained and reduced. Consequently, the electronic devices within the rack cabinet can be continuously and normally operated.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A cooling system, comprising:
a computer room comprising an inner space, an airflow exhaust gate and an airflow intake gate;
at least one rack cabinet installed within said inner space of said computer room;
at least one air conditioner installed within said inner space of said computer room for cooling said inner space and adjusting a temperature of said inner space, wherein said air conditioner comprises an airflow inlet and an airflow outlet;
a first airflow path switching unit in fluid communication with said airflow inlet and said airflow exhaust gate, wherein said first airflow path switching unit comprises a first blocking element; and
a second airflow path switching unit in fluid communication with said airflow outlet and said airflow intake gate, wherein said second airflow path switching unit comprises a second blocking element,
wherein an airflow path is switched by said first blocking element and said second blocking element according to an operating status of said air conditioner, so that said computer room is operated in an internal circulation mode or an external circulation mode.

2. The cooling system according to claim 1 wherein said air conditioner is located in the vicinity of said airflow exhaust gate and said airflow intake gate, and comprises a heat exchanger and a first airflow driving device.

3. The cooling system according to claim 1 wherein said first airflow path switching unit further comprises a first internal circulation path and a first external circulation path, wherein through said first internal circulation path, said airflow inlet and said inner space are in fluid communication with each other, wherein through said first external circulation path, said airflow exhaust gate and said inner space are in fluid communication with each other, wherein said first external circulation path or said first internal circulation path is selectively blocked by said first blocking element according to said operating status of said air conditioner, so that said computer room is operated in said internal circulation mode or said external circulation mode.

4. The cooling system according to claim 3 wherein said second airflow path switching unit further comprises a second internal circulation path and a second external circulation path, wherein through said second internal circulation path, said airflow outlet and said inner space are in fluid communication with each other, wherein through said second external circulation path, said airflow intake gate and said inner space are in fluid communication with each other, wherein said second external circulation path or said second internal circulation path is selectively blocked by said second blocking element according to said operating status of said air conditioner, so that said computer room is operated in said internal circulation mode or said external circulation mode.

5. The cooling system according to claim 4 wherein said first blocking element and said second blocking element are air doors.

6. The cooling system according to claim 4 wherein said first airflow path switching unit further comprises a first fan, which is located in said first external circulation path for driving airflow, wherein said second airflow path switching unit further comprises a second fan, which is located in said second external circulation path for driving airflow.

7. The cooling system according to claim 6 wherein if said air conditioner is normally operated or has sufficient cooling capability, said first internal circulation path and said second internal circulation path are in fluid communication and said first fan and said second fan are disabled, so that said computer room is operated in said internal circulation mode.

8. The cooling system according to claim 6 wherein if said air conditioner is abnormal or damaged or has insufficient cooling capability, said first external circulation path and said second external circulation path are in fluid communication and said first fan and said second fan are enabled to drive airflow, so that said computer room is operated in said external circulation mode.

9. The cooling system according to claim 8 wherein when said computer room is operated in said external circulation mode, an ambient cool airflow is inhaled into said inner space through said airflow intake gate, and a heated airflow within said computer room is exhausted to surroundings through said airflow exhaust gate.

10. The cooling system according to claim 6 further comprising:
at least one detecting unit for detecting said operating status of said air conditioner, thereby issuing a corresponding detecting signal; and
a controlling unit connected with said detecting unit, said first blocking element and said second blocking element, wherein in response to said detecting signal, a first switching signal and a second switching signal are respectively outputted from said controlling unit to said first blocking element and said second blocking element, so that said first blocking element and said second blocking element are controlled by the said controlling unit according to said operating status of said air conditioner.

11. The cooling system according to claim 10 wherein said controlling unit is further electrically connected to said first fan and said second fan, wherein in response to said detecting signal, a first driving signal and a second driving signal are respectively outputted from said controlling unit to said first fan and said second fan, so that said first fan and said second fan are controlled by the said controlling unit according to said operating status of said air conditioner.

12. The cooling system according to claim 1, further comprising:
a guiding device having an inlet, an outlet and an airflow passage, wherein said inlet is in fluid communication with a hot zone defined by a plurality of rack cabinets and said outlet is in fluid communication with an inlet of said first airflow path switching unit; and
a second airflow driving device disposed in said airflow passage of said guiding device.

13. A cooling system, comprising:
a computer room comprising an inner space, an airflow exhaust gate and an airflow intake gate;
at least one rack cabinet installed within said inner space of said computer room;
at least one air conditioner installed within said inner space and adjusting a temperature of said inner space, so that the heat is removed by said air conditioner, wherein said air conditioner comprises an airflow inlet and an airflow outlet;
a first airflow path switching unit in fluid communication with said airflow inlet and said airflow exhaust gate, wherein said first airflow path switching unit comprises a first blocking element; and
a second airflow path switching unit in fluid communication with said airflow outlet and said airflow intake gate, wherein said second airflow path switching unit comprises a second blocking element,
wherein an airflow path is switched by said first blocking element and said second blocking element according to an operating status of said air conditioner, so that said computer room is operated in an internal circulation mode or an external circulation mode, wherein when said computer room is operated in said external circulation mode, an ambient cool airflow is inhaled into said inner space through said airflow intake gate, and a heated airflow within said computer room is exhausted to surroundings through said airflow exhaust gate.

14. The cooling system according to claim 13 wherein said first airflow path switching unit further comprises a first internal circulation path and a first external circulation path, wherein through said first internal circulation path, said airflow inlet and said inner space are in fluid communication with each other, wherein through said first external circulation path, said airflow exhaust gate and said inner space are in fluid communication with each other, wherein said first external circulation path or said first internal circulation path is selectively blocked by said first blocking element according to said operating status of said air conditioner, so that said computer room is operated in said internal circulation mode or said external circulation mode.

15. The cooling system according to claim 14 wherein said second airflow path switching unit further comprises a second internal circulation path and a second external circulation path, wherein through said second internal circulation path, said airflow outlet and said inner space are in fluid communication with each other, wherein through said second external circulation path, said airflow intake gate and said inner space are in fluid communication with each other, wherein said second external circulation path or said second internal circulation path is selectively blocked by said second blocking element according to said operating status of said air conditioner, so that said computer room is operated in said internal circulation mode or said external circulation mode.

16. The cooling system according to claim 15 wherein said first airflow path switching unit further comprises a first fan, which is located in said first external circulation path for driving airflow, wherein said second airflow path switching unit further comprises a second fan, which is located in said second external circulation path for driving airflow.

17. The cooling system according to claim 16 wherein if said air conditioner is normally operated or has sufficient cooling capability, said first internal circulation path and said second internal circulation path are in fluid communication and said first fan and said second fan are disabled, so that said computer room is operated in said internal circulation mode.

18. The cooling system according to claim 16 wherein if said air conditioner is abnormal or damaged or has insufficient cooling capability, said first external circulation path and said second external circulation path are in fluid communication and said first fan and said second fan are enabled to drive airflow, so that said computer room is operated in said external circulation mode.

19. A cooling system, comprising:
a computer room comprising an inner space, an airflow exhaust gate and an airflow intake gate;
at least one rack cabinet installed within said inner space of said computer room;
at least one air conditioner installed within said inner space for adjusting a temperature of said inner space, wherein said air conditioner comprises an airflow inlet and an airflow outlet;
a first airflow path switching unit in fluid communication with said airflow inlet and said airflow exhaust gate, wherein said first airflow path switching unit comprises a first blocking element;
a second airflow path switching unit in fluid communication with said airflow outlet and said airflow intake gate, wherein said second airflow path switching unit comprises a second blocking element;
at least one detecting unit for detecting an operating status of said air conditioner and issuing a corresponding detecting signal; and
a controlling unit connected with said detecting unit, said first blocking element and said second blocking element for controlling said first blocking element and said second blocking element to switch an airflow path in response to said detecting signal, so that said computer room is operated in an internal circulation mode or an external circulation mode.

20. The cooling system according to claim 19 wherein when said computer room is operated in said external circulation mode, an ambient cool airflow is inhaled into said inner space through said airflow intake gate, and a heated airflow within said computer room is exhausted to surroundings through said airflow exhaust gate.
